(19) United States
(12) Patent Application Publication
(10) Pub. No.: US 2012/0274190 A1
(43) Pub. Date: Nov. 1, 2012

(54) ELECTRONIC DEVICE ENCLOSURE

(75) Inventors: GANG-QIANG QIN, Shenzhen City (CN); XU YANG, Shenzhen City (CN)

(73) Assignees: HON HAI PRECISION INDUSTRY CO., LTD., Tu-Cheng (TW); HONG FU JIN PRECISION INDUSTRY (SHENZHEN) CO., LTD., Shenzhen City (CN)

(21) Appl. No.: 13/433,503

(22) Filed: Mar. 29, 2012

(30) Foreign Application Priority Data
Apr. 27, 2011 (CN) 201110106723.6

(51) Int. Cl. H05K 5/02

(52) U.S. Cl. 312/223.1

(57) ABSTRACT

An electronic device enclosure includes an enclosure and a strengthening device. The enclosure includes a bottom plate. The strengthening device includes a first strengthening member and a second strengthening member. The second strengthening member includes a receiving portion engaged with the receiving portion. The first strengthening member is attached to the bottom plate in a first direction; and the second strengthening member is attached to the bottom plate in a second direction that intersected with the first direction.

### BACKGROUND

1. Technical Field

The present disclosure relates to electronic device enclosures, more particularly to an electronic device enclosure for data center servers.

2. Description of Related Art

Blade and rack-mounted servers are popular form factors for data center servers. In order to achieve high performance, a plurality of rack-mounted servers is clustered in an enclosure, such as a container. A bottom plate of the enclosure is often damaged due to supporting the plurality of rack-mounted servers.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an isometric view of an electronic device enclosure in accordance with an embodiment.

FIG. 2 is an exploded, isometric view of FIG. 1.

FIG. 3 is an isometric view of a first strengthening member of the electronic device enclosure of FIG. 2.

FIG. 4 is an assembled view of FIG. 2.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

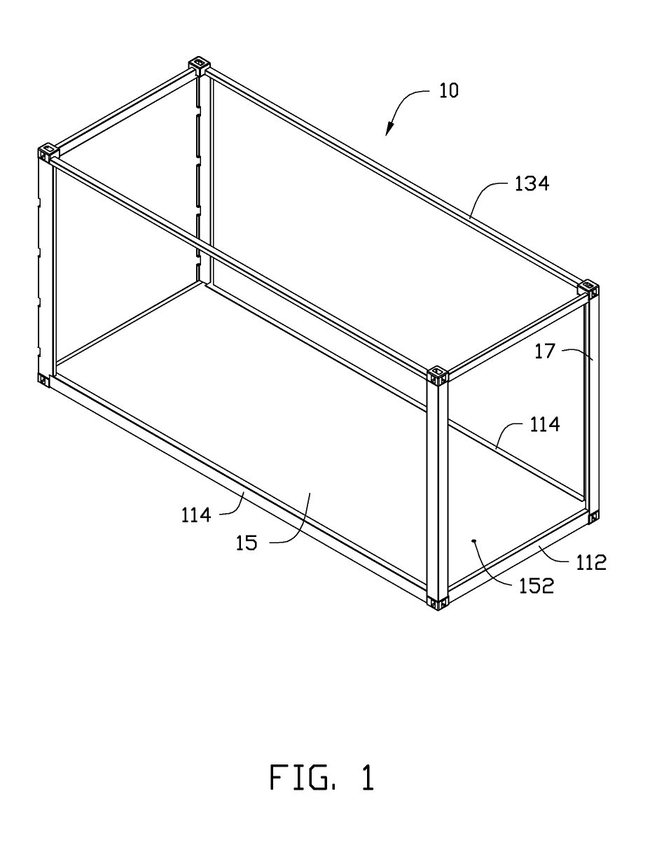

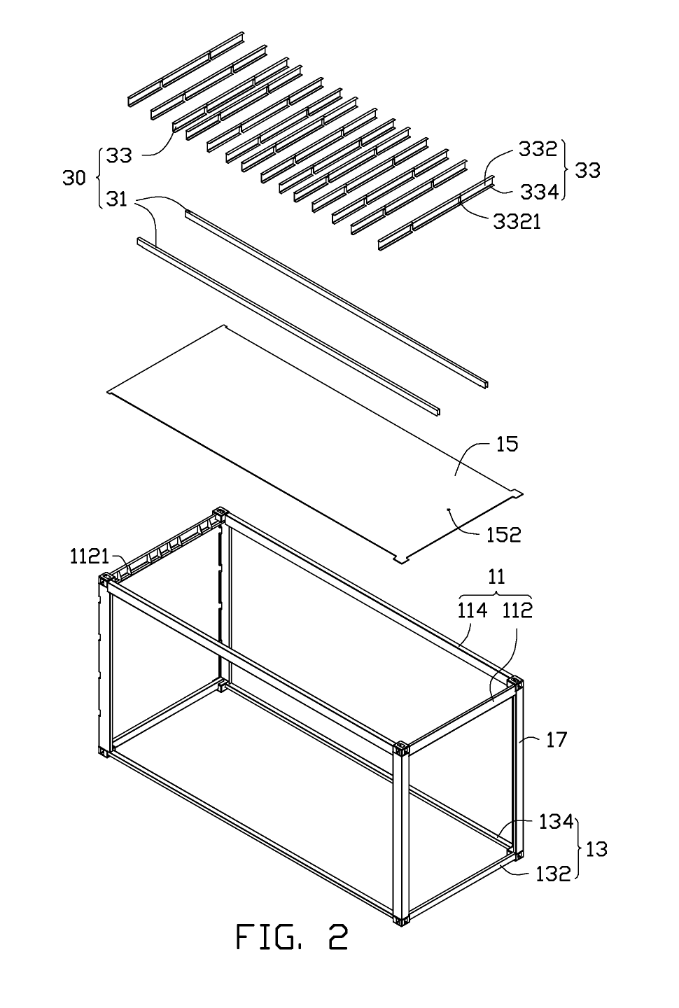

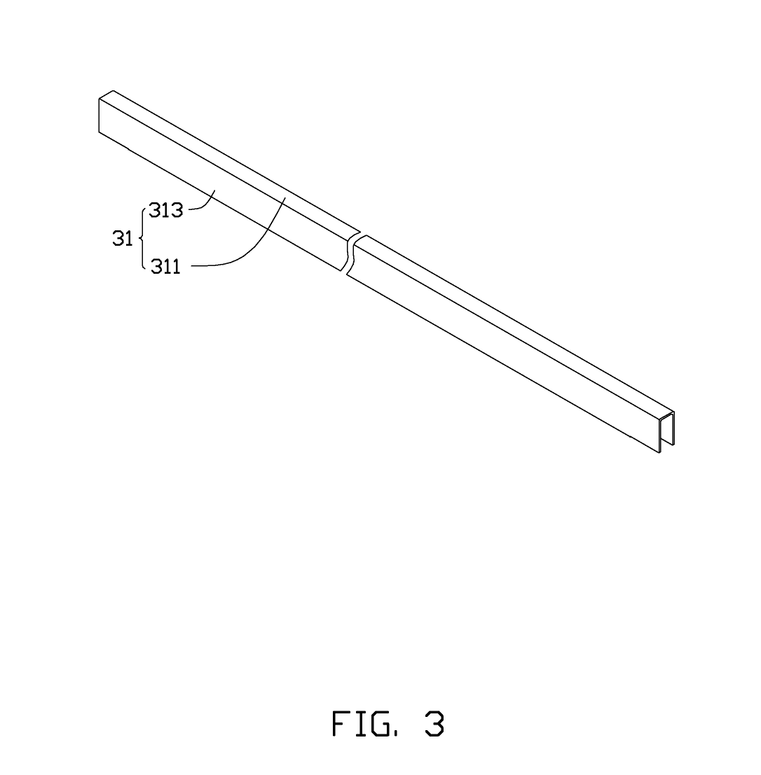

Referring to FIGS. 1-3, an electronic device enclosure in accordance with an embodiment includes an enclosure 10, and a strengthening device 30 attached to the enclosure 10. In one embodiment, the enclosure 10 is a container for receiving blade and rack-mounted servers.

The enclosure 10 includes a first frame 11, a second frame 13, a bottom plate 15, and four posts 17 located between the first frame 11 and the second frame 13. The first frame 11 includes two first poles 112 and two second poles 114. A plurality of strengthening ribs 1121 is located on the inner surface of each of the two first poles 112. In one embodiment, the second frame 13 has a same configuration to the first frame 11, and includes two third poles 132 and two fourth poles 134.

The bottom plate 15 defines a plurality of securing holes 152 (only one is shown in FIGS. 1-4). The plurality of securing holes 152 is configured to align with a plurality of mounting holes of blade and rack-mounted servers. Many fixing members are engaged into the plurality of securing holes 152 and mounting holes, to secure the blade and rack-mounted servers on the bottom plate 15. In one embodiment, each of the two first poles 112 is substantially perpendicular to each of the two second poles 114 and each of the four posts 17, each of the plurality of strengthening ribs 1121 is a triangle, and the bottom plate 15 consists of metal.

The strengthening device 30 includes two first strengthening members 31 and a plurality of second strengthening members 33 attached to the two first strengthening members 31. Each of the two first strengthening members 31 includes a first panel 311 and two second panels 313 connected to the first panel 311. In one embodiment, the first panel 311 is substantially perpendicular to each of the two second panels 313, and a width of the first panel 311 is less than that of each of the two second panels 313. In one embodiment, the first strengthening member 31 is a solid post.

Each of the plurality of second strengthening members 33 includes a panel 332 and two flanges 334 extending from opposite edges of the panel 332. In one embodiment, the second strengthening member 33 is substantially U-shaped, the two flanges 334 are substantially parallel to each other and substantially perpendicular to the panel 332. Two receiving portions 3321 are located on each of the plurality of second strengthening members 33. In one embodiment, each of the receiving portions 3321 is passed through the panel 332 and one of the two flanges 334, and each of the receiving portions 3321 is L-shaped. In one embodiment, each of the plurality of second strengthening members 33 has a same configuration as each of the two first strengthening members 31.

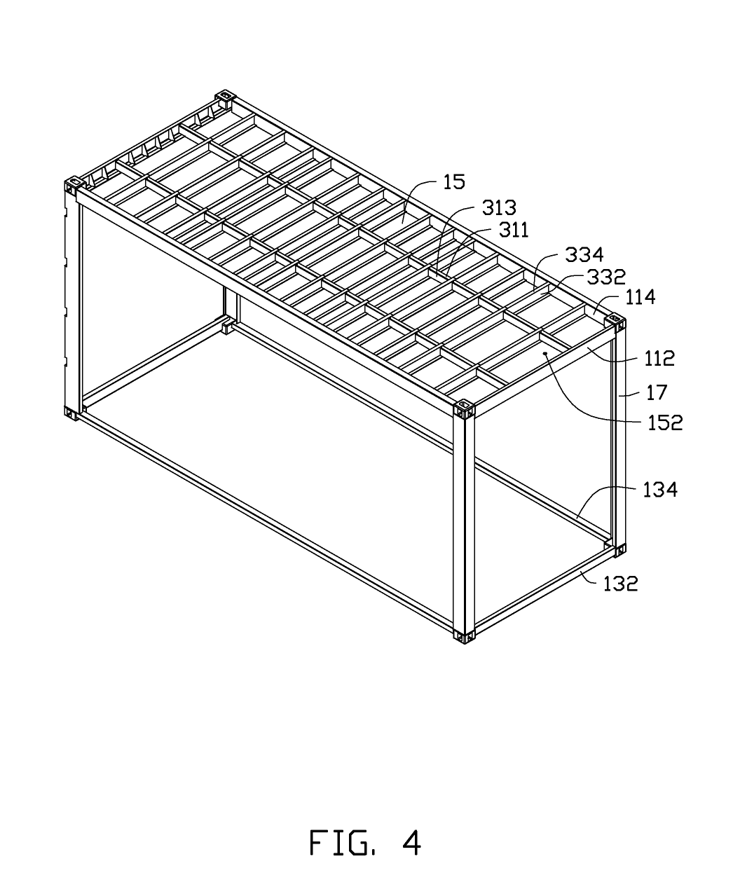

Referring to FIG. 4, in assembly, the bottom plate 15 is secured to the first frame 11 by means, such as screws, jointing. The two first strengthening members 31 are located between the two first poles 112 by means, such as screws, jointing. Each of the plurality of second strengthening members 33 is located between the two second poles 114 in a first direction intersected with the two second poles 114 and above the two first strengthening members 31. In one embodiment, the first direction is substantially perpendicular to the two second poles 114. Each of the two first strengthening members 31 is received in each of the two receiving portions 3321, and the each of the two first strengthening members 31 are secured to the receiving portions 3321 by jointing. Each of the plurality of second strengthening members 33 is secured to the two second poles 114 by means such as screws and/or jointing. In one embodiment, each of the two first strengthening members 31 is substantially perpendicular to each of the plurality of second strengthening members 33 and each of the two first poles 112, so that the two first strengthening members 31 and the plurality of second strengthening members 33 together define a plurality of panes. In one embodiment, each pane is rectangle.

In one embodiment, the bottom plate 15 is made of steel, and the strengthening device 30 is secured to the bottom plate 15. Therefore, the bottom plate 15 can endure a plurality of rack-mounted servers.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. An electronic device enclosure comprising:
an enclosure comprising a bottom plate;
a strengthening device includes a first strengthening member and a second strengthening member, the second strengthening member comprising a receiving portion, and the first strengthening member engaged with the receiving portion;
wherein the first strengthening member is attached to the bottom plate in a first direction; and the second strengthening member is attached to the bottom plate in a second direction that intersects with the first direction.

2. The electronic device enclosure of claim 1, wherein the first direction is substantially perpendicular to the second direction.

3. The electronic device enclosure of claim 1, wherein the second strengthening member comprises a panel and a flange extending from the panel, and the receiving portion extends through the panel and the flange.

4. The electronic device enclosure of claim 1, wherein the receiving portion is a slot and L-shaped.

5. The electronic device enclosure of claim 1, wherein the enclosure further comprises a first frame mounted to the bottom plate, the first frame comprises a first pole, and the first strengthening member is substantially perpendicular to the first pole.

6. The electronic device enclosure of claim 5, wherein the first pole comprises a plurality of strengthening ribs, and a cross-section of each rib is triangle.

7. The electronic device enclosure of claim 1, wherein the bottom plate consists of metal.

8. An electronic device enclosure comprising:
an enclosure comprising a bottom plate;
a strengthening device includes two first strengthening members and a plurality of second strengthening members; the two first strengthening member being substantially parallel to each other; each second strengthening member comprising two receiving portions, and the two first strengthening members engaged with the two receiving portions of the each second strengthening member;
wherein the two first strengthening members are attached to the bottom plate in a first direction; and the plurality of second strengthening members is attached to the bottom plate in a second direction that intersected with the first direction, so that the two first strengthening members and the plurality of second strengthening members together define a plurality of panes.

9. The electronic device enclosure of claim 8, wherein the first direction is substantially perpendicular to the second direction.

10. The electronic device enclosure of claim 8, wherein each second strengthening member comprises a panel and a flange extending from the panel, and each receiving portion extends through the panel and the flange.

11. The electronic device enclosure of claim 8, wherein each receiving portion is a slot and L-shaped.

12. The electronic device enclosure of claim 8, wherein the enclosure further comprises a first frame mounted to the bottom plate, the first frame comprises a first pole, and each first strengthening member is substantially perpendicular to the first pole.

13. The electronic device enclosure of claim 12, wherein the first pole comprises a plurality of strengthening ribs, and a cross-section of each rib is triangle.

14. The electronic device enclosure of claim 8, wherein the bottom plate consists of metal.
